(19) United States
(12) Patent Application Publication
(10) Pub. No.: US 2026/0230007 A1
(43) Pub. Date: Aug. 6, 2026

(54) SINGLE-ELECTRODE NORMALIZED SETTING CIRCUIT OF ULTRASONIC MOTOR

(71) Applicants: Nanjing Hang Da Chao Kong Technology Co., Ltd., Nanjing (CN); Nanjing University of Aeronautics and Astronautics, Nanjing (CN)

(72) Inventors: Chunsheng ZHAO, Nanjing (CN); Lin YANG, Nanjing (CN); Dazhi LIANG, Nanjing (CN)

(21) Appl. No.: 18/728,640

(22) PCT Filed: Apr. 25, 2024
(86) PCT No.: PCT/CN2024/089735

§ 371 Date: Jul. 12, 2024

(30) Foreign Application Priority Data
Oct. 26, 2023 (CN) 202311405009.6

(51) Int. Cl. H02N 2/00

(52) U.S. Cl. CPC H02N 2/0075

(57) ABSTRACT

A single-electrode normalized setting circuit of an ultrasonic motor is provided, in which a load resistor and an alternating current ammeter are connected in series, and a potentiometer and a single-pole double-throw switch are connected in series. Two series branches are connected in parallel. A second plug is located on an ultrasonic motor driver side, and a driving socket is located on an ultrasonic motor side. Terminals of a first plug are connected to corresponding ports of the driving socket and the second plug. The voltage feedback terminal of the first plug is connected to a connecting point between the alternating current ammeter and the single-pole double-throw switch, the ground terminal of the first plug is connected to a connecting point between the load resistor and the potentiometer, and a normalized setting resistor is connected between a voltage feedback terminal and a ground terminal of the driving socket.

### CROSS-REFERENCE TO RELATED APPLICATION

This patent application is a national stage of International Application No. PCT/CN2024/089735, filed on Apr. 25, 2024, which claims the priority of Chinese Patent Application No. 202311405009.6 filed with the China National Intellectual Property Administration on Oct. 26, 2023, and entitled “Single-electrode normalized setting circuit of ultrasonic motor”. Both of the aforementioned applications are hereby incorporated by reference in their entireties.

### TECHNICAL FIELD

The present disclosure relates to the technical field of ultrasonic motors, and in particular to a single-electrode normalized setting circuit of an ultrasonic motor.

### BACKGROUND

Piezoelectric ceramics are functional ceramic materials capable of converting mechanical energy and electrical energy into each other. When pressure is applied to both ends of the piezoelectric ceramic wafer, electrostatic charges with opposite polarities are generated on electrodes at both ends of the piezoelectric ceramic. This effect is called positive piezoelectric effect. Similarly, voltages applied to both ends of the piezoelectric ceramic make the piezoelectric ceramic produce corresponding volume deformation, and this effect is called inverse piezoelectric effect.

Traveling-wave ultrasonic motor uses the inverse piezoelectric effect of annular piezoelectric ceramics to achieve torque output to do work and produce rotation. Meanwhile, the positive piezoelectric effect of some arc segments of the annular piezoelectric ceramics is applied as a test sensor, so as to reflect the current excitation situation of the annular piezoelectric ceramics. This arc segment is also called single-electrode for short.

At present, the electrical performance of the single-electrode is affected by technological factors such as design, gluing, assembly, interface and stress. Even if the same batch of annular piezoelectric ceramics with different numbers are applied with the same excitation voltage at both ends, the amount of charge on the single-electrode is still quite different, and the sensing voltage value in the subsequent loop is also quite different, leading to a situation that the single-electrode cannot truly reflect the current excitation state of the annular piezoelectric ceramics. This is also the shortcoming of the traveling-wave ultrasonic motor at present, which greatly limits the development and engineering application of the traveling-wave ultrasonic motors.

### SUMMARY

An objective of the present disclosure is to provide a single-electrode normalized setting circuit of an ultrasonic motor, such that a voltage value of a single-electrode signal can truly reflect a current excitation state of annular piezoelectric ceramics, and an excitation voltage and a single-electrode signal voltage are always kept at a correct proportional relationship.

To achieve the objective above, the present disclosure employs the following technical solution.

A single-electrode normalized setting circuit of an ultrasonic motor includes a load resistor, an alternating current ammeter, a potentiometer, a single-pole double-throw switch, a first plug, a second plug, a driving socket, and a normalized setting resistor.

The load resistor and the alternating current ammeter are connected in series to form a first branch, the potentiometer and the single-pole double-throw switch are connected in series to form a second branch, and the first branch and the second branch are connected in parallel to form a first wiring terminal and a second wiring terminal. The first wiring terminal is a wiring terminal formed by connecting the alternating current ammeter and the single-pole double-throw switch, and the second wiring terminal is a wiring terminal formed by connecting the load resistor and the potentiometer. The second plug is located on an ultrasonic motor driver side, and the driving socket is located on an ultrasonic motor side.

A sin signal terminal, a cos signal terminal, a voltage feedback terminal and a ground terminal of the first plug are connected to corresponding ports of the driving socket in one-to-one correspondence. The sin signal terminal, the cos signal terminal and the ground terminal of the first plug are connected to corresponding ports of the second plug in one-to-one correspondence. The voltage feedback terminal of the first plug is connected to the first wiring terminal, and the ground terminal of the first plug is connected to the second wiring terminal.

The normalized setting resistor is connected between a bonding pad where a voltage feedback terminal of the driving socket is located and a bonding pad where a ground terminal is located.

A difference between a resistance value of the normalized setting resistor and a measured resistance value is less than a predetermined value. The measured resistance value is a resistance value of the potentiometer in a first state.

An adjusting process of the first state includes: switching the single-pole double-throw switch to an ON side, and adjusting the resistance value of the potentiometer to a minimum value; adjusting an output frequency of an ultrasonic motor driver, such that a rotating speed of the ultrasonic motor reaches a highest speed; adjusting the potentiometer to stabilize a current value displayed by the alternating current ammeter to a predetermined current value; and turning off an output of the ultrasonic motor driver and switching the single-pole double-throw switch to an OFF side, such that the potentiometer is in the first state.

According to specific embodiments of the present disclosure, the present disclosure has the following technical effects.

A single-electrode normalized setting circuit of an ultrasonic motor provided by the embodiment of the present disclosure includes a load resistor, an alternating current ammeter, a potentiometer, a single-pole double-throw switch, a first plug, a second plug, a driving socket, and a normalized setting resistor. By adjusting the potentiometer, when any ultrasonic motor rotates at the highest speed, due to the fact that a voltage feedback terminal FB of the first plug is connected to a first wiring terminal, and a ground terminal GND of the first plug is connected to a second wiring terminal, values of current formed by FB/GND single-electrode signal outputs flowing through the load resistor are both set to a predetermined current value in a normalized setting manner. According to the embodiment of the present disclosure, the voltage value of the single-electrode signal can truly reflect the current excitation state of annular piezoelectric ceramic, thus keeping an excitation voltage and a single-electrode signal voltage always at a correct proportional relationship.

### BRIEF DESCRIPTION OF THE DRAWINGS

To illustrate the technical solution of the embodiments of the present disclosure or in the prior art more clearly, the accompanying drawings needing to be used in the embodiments of the present disclosure are briefly introduced below.

FIG. 1 is a structural diagram of a single-electrode normalized setting circuit of an ultrasonic motor according to an embodiment of the present disclosure.

In the drawings:
R1—load resistor, M1—alternating current ammeter, R2—potentiometer, K1—single-pole double-throw switch, P1—first plug, P2—second plug, P3—driving socket, R3—normalized setting resistor.

### DETAILED DESCRIPTION OF THE EMBODIMENTS

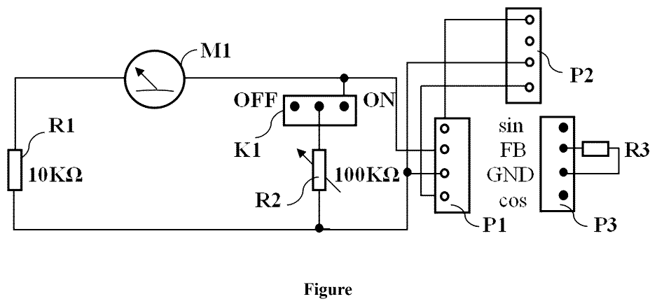

Referring to FIG. 1, a single-electrode normalized setting circuit of an ultrasonic motor in this embodiment includes a load resistor R1, an alternating current ammeter M1, a potentiometer R2, a single-pole double-throw switch K1, a first plug P1, a second plug P2, a driving socket P3, and a normalized setting resistor R3. The load resistor R1, the alternating current ammeter M1, the potentiometer R2, the single-pole double-throw switch K1 and the first plug P1 are located on a normalized setting circuit side, the second plug P2 is located on an ultrasonic motor driver side, and the driving socket P3 and the normalized setting resistor R3 are located on an ultrasonic motor side.

The load resistor R1 and the alternating current ammeter M1 are connected in series to form a first branch, the potentiometer R2 and the single-pole double-throw switch K1 are connected in series to form a second branch, and the first branch and the second branch are connected in parallel to form a first wiring terminal and a second wiring terminal. The first wiring terminal is a wiring terminal formed by connecting the alternating current ammeter M1 and the single-pole double-throw switch K1. The second wiring terminal is a wiring terminal formed by connecting the load resistor R1 and the potentiometer R2.

A sin signal terminal, a cos signal terminal, a voltage feedback terminal FB and a ground terminal GND of the first plug P1 are connected to corresponding ports of the driving socket P3 in one-to-one correspondence. The sin signal terminal, the cos signal terminal and the ground terminal GND of the first plug P1 are connected to corresponding ports of the second plug P2 in one-to-one correspondence. The voltage feedback terminal FB of the first plug P1 is connected to the first wiring terminal, and the ground terminal GND of the first plug P1 is connected to the second wiring terminal.

The normalized setting resistor R3 is connected between a bonding pad where a voltage feedback terminal FB of the driving socket P3 is located and a bonding pad where a ground terminal GND is located.

A difference between a resistance value of the normalized setting resistor R3 and a measured resistance value is less than a predetermined value. The measured resistance value is a resistance value of the potentiometer R2 in a first state. In practical application, the resistance value of the normalized setting resistor R3 may be equal to the measured resistance value.

An adjusting process of the first stage is as follows: first, switching the single-pole double-throw switch K1 to an ON side, and adjusting the resistance value of the potentiometer R2 to a minimum value; secondly, adjusting an output frequency of an ultrasonic motor driver, such that a rotating speed of the ultrasonic motor reaches a highest speed; afterwards, adjusting the potentiometer R2 to stabilize a current value displayed by the alternating current ammeter M1 to a predetermined current value; and turning off an output of the ultrasonic motor driver and switching the single-pole double-throw switch K1 to an OFF side, such that the potentiometer R2 is in the first state.

It needs to be noted that the minimum resistance value of the potentiometer R2 is set at the factory. Potentiometers with different processes may have different minimum values, which may or may not be 0. Different types of ultrasonic motors have different highest rotating speeds, and the highest speeds are also set at the factory. In this embodiment, before normalized setting, the minimum resistance value of the potentiometer R2 and the highest speed of the ultrasonic motor are both known in advance.

In an example, a resistance value of the load resistor R1 may be 10 KΩ.

In an example, a maximum current value of the alternating current ammeter M1 is greater than or equal to 50 μA, and the alternating current ammeter M1 is a high-frequency alternating current ammeter.

In an example, a maximum resistance value of the potentiometer R2 may be 100 KΩ.

In an example, the predetermined current value may be 50 μA.

In an example, the first plug P1 and the second plug P2 may both be four-core hole plugs. The driving socket P3 may be a four-core pin socket. The four-core hole plug is a 2510 four-core hole plug, and the four-core pin socket is a 2510 four-core pin socket.

In an example, the single-pole double-throw switch K1 may be a single-pole double-throw ping-pong switch.

The process of achieving the setting by the single-electrode normalized setting circuit of the ultrasonic motor of the above embodiment will be introduced below.

First. The first plug p1 on the normalized setting circuit side is connected to the driving socket P3 on the ultrasonic motor side. Three lines, e.g., sin/GND/cos, of the first plug P1 on the normalized setting circuit side are connected to the second plug P2 on the ultrasonic motor side, an output driving signal of the ultrasonic motor driver is used for driving the ultrasonic motor to rotate via the first plug P1 and the driving socket P3. Two lines, e.g., FB/GND, of a single-electrode signal on the ultrasonic motor side are connected to the normalized setting circuit via the driving socket P3 and the first plug P1. The potentiometer R2 and the single-pole double-throw switch K1 are connected in series, and the alternating current ammeter M1 and the load resistor R1 are connected in series, and then the two series circuits are connected to the FB/GND lines in parallel to form a single-electrode normalized setting circuit of the ultrasonic motor.

Based on the above connection relationship, the setting method is specifically as follows.

The ultrasonic motor, the normalized setting circuit and the ultrasonic motor driver are connected. On the normalized setting circuit side, the first plug P1 is inserted into the driving socket P3, and then three lines, e.g., sin/GND/cos, of the second plug P2 are connected to an output terminal of the ultrasonic motor driver. Two lines, e.g., FB/GND, of the first plug P1 on the normalized setting circuit side are used to connect a single-electrode signal of the ultrasonic motor on the driving socket P3 to the normalized setting circuit.

The normalized setting of the single-electrode signal is described as follows. First, the single-pole double-throw switch K1 is switched to an ON side, such that the potentiometer R2 is connected to the FB line, and the resistance value of the potentiometer R2 is adjusted to a minimum value. Secondly, an output frequency of the ultrasonic motor driver is adjusted, such that the rotating speed of the ultrasonic motor reaches a highest speed. Thirdly, the potentiometer R2 is adjusted to stabilize a current value displayed by the alternating current ammeter M1 to 50 μA. Then, the output of the ultrasonic motor driver is turned off, the single-pole double-throw switch K1 is switched to an OFF side to separate the potentiometer R2 from the FB line. Finally, the resistance value of the potentiometer R2 is measured, another E96 series resistor having a resistance value closest to the resistance value is taken as a normalized setting resistor R3, and the normalized setting resistor R3 is directly welded between two FB/GND bonding pads on the back of the driving socket P3 at the ultrasonic motor side, and the single-electrode normalized setting process is completed.

According to the embodiment of the present disclosure, by adjusting the potentiometer R2, when any ultrasonic motor is at the highest rotating speed, values of current flowing through the load resistor R1 and outputted by the FB/GND single-electrode signal are both set to 50 μA in a normalized setting manner, thus obtaining the normalized setting resistor R3. According to the present disclosure, the shortcoming that the single-electrode signal of the traveling-wave ultrasonic motor cannot truly reflect the current excitation state of the annular piezoelectric ceramics is overcomed, and a more solid foundation is laid for the research and development and even engineering application of traveling-wave ultrasonic motor products in the future.

Specific examples are used herein for illustration of the principles and implementation methods of the present disclosure. The description of the above embodiments is merely used to help understand the device and its core principles of the present disclosure. For those of ordinarily skilled in the art, based on the ideas of the present invention, there will be changes in the specific embodiments and scope of application, and the content of this specification should not be understood as the limitation to the present disclosure.

What is claimed is:

1. A single-electrode normalized setting circuit of an ultrasonic motor, comprising a load resistor, an alternating current ammeter, a potentiometer, a single-pole double-throw switch, a first plug, a second plug, a driving socket, and a normalized setting resistor, wherein;
the load resistor and the alternating current ammeter are connected in series to form a first branch, the potentiometer and the single-pole double-throw switch are connected in series to form a second branch, and the first branch and the second branch are connected in parallel to form a first wiring terminal and a second wiring terminal; the first wiring terminal is a wiring terminal formed by connecting the alternating current ammeter and the single-pole double-throw switch, and the second wiring terminal is a wiring terminal formed by connecting the load resistor and the potentiometer; the second plug is located on an ultrasonic motor driver side, and the driving socket is located on an ultrasonic motor side;
a sin signal terminal, a cos signal terminal, a voltage feedback terminal and a ground terminal of the first plug are connected to corresponding ports of the driving socket in one-to-one correspondence; the sin signal terminal, the cos signal terminal and the ground terminal of the first plug are connected to corresponding ports of the second plug in one-to-one correspondence; the voltage feedback terminal of the first plug is connected to the first wiring terminal, and the ground terminal of the first plug is connected to the second wiring terminal;
the normalized setting resistor is connected between a bonding pad where a voltage feedback terminal of the driving socket is located and a bonding pad where a ground terminal is located;
a difference between a resistance value of the normalized setting resistor and a measured resistance value is less than a predetermined value, and the measured resistance value is a resistance value of the potentiometer in a first state;
an adjusting process of the first state comprises:
switching the single-pole double-throw switch to an ON side, and adjusting the resistance value of the potentiometer to a minimum value;
adjusting an output frequency of an ultrasonic motor driver, such that a rotating speed of the ultrasonic motor reaches a highest speed;
adjusting the potentiometer to stabilize a current value displayed by the alternating current ammeter to a predetermined current value; and
turning off an output of the ultrasonic motor driver and switching the single-pole double-throw switch to an OFF side, such that the potentiometer is in the first state.

2. The single-electrode normalized setting circuit according to claim 1, wherein a resistance value of the load resistor is 10 KΩ.

3. The single-electrode normalized setting circuit according to claim 1, wherein a maximum current value of the alternating current ammeter is greater than or equal to 50 μA.

4. The single-electrode normalized setting circuit according to claim 1, wherein a maximum resistance value of the potentiometer is 100 KΩ.

5. The single-electrode normalized setting circuit according to claim 3, wherein the predetermined current value is 50 μA.

6. The single-electrode normalized setting circuit according to claim 1, wherein the first plug and the second plug are both four-core hole plugs, and the driving socket is a four-core pin socket.

7. The single-electrode normalized setting circuit according to claim 1, wherein the single-pole double-throw switch is a single-pole double-throw ping-pong switch.
